(19) United States
(12) Patent Application Publication
(10) Pub. No.: US 2017/0033170 A1
(43) Pub. Date: Feb. 2, 2017

(54) ORGANIC LIGHT EMITTING DIODE DISPLAY

(71) Applicant: SAMSUNG DISPLAY CO., LTD., Yongin-si (KR)

(72) Inventors: Eung Do Kim, Seoul (KR); Dong Chan Kim, Gunpo-si (KR); Won Jong Kim, Suwon-si (KR); Dong Kyu Seo, Hwaseong-si (KR); Ji Hye Lee, Incheon (KR); Da Hea Im, Incheon (KR); Sang Hoon Yim, Suwon-si (KR); Yoon Hyeung Cho, Yongin-si (KR); Won Suk Han, Yongin-si (KR)

(21) Appl. No.: 15/015,081

(22) Filed: Feb. 3, 2016

(30) Foreign Application Priority Data
Jul. 27, 2015 (KR) 10-2015-0106056

(51) Int. Cl. H01L 27/32; H01L 51/52

(52) U.S. Cl. CPC H01L 27/3262; H01L 27/3248; H01L 51/5275; H01L 27/3258; H01L 27/3246; H01L 51/524; H01L 2251/301

(57) ABSTRACT

An organic light emitting diode display includes: a first substrate; a switching thin film transistor on the first substrate; a driving thin film transistor on the first substrate; an organic light emitting diode connected to the driving thin film transistor; and a capping layer on the organic light emitting diode, the capping layer including an anisotropic material having a refractive index in a horizontal direction that is greater than a refractive index in a vertical direction.

### CROSS-REFERENCE TO RELATED APPLICATION

This application claims priority to, and the benefit of, Korean Patent Application No. 10-2015-0106056, filed in the Korean Intellectual Property Office on Jul. 27, 2015, the entire content of which is incorporated herein by reference.

### BACKGROUND

1. Field

One or more aspects of example embodiments of the present invention relate to an organic light emitting diode display.

2. Description of the Related Art

An organic light emitting diode (OLED) display includes two electrodes and an organic emission layer therebetween. Electrons injected from one electrode, and holes injected from another electrode, are combined in the organic emission layer to generate excitons, and the generated excitons release energy to emit light. The OLED display displays an image (e.g., a predetermined image) through such light emission.

The OLED display may have reduced thickness and weight, because the

OLED display has a self-luminance characteristic and does not require an additional light source, unlike a liquid crystal display (LCD). In addition, the OLED display is receiving attention as a next generation display device, because it features high quality characteristics, such as low power consumption, high luminance, and/or high response speed.

The OLED display includes an OLED, and the OLED includes an anode, a cathode, and an organic emission layer between the anode and the cathode. A capping layer may be formed on the cathode, so that light extracting/emission efficiency may be improved. However, internal light reflection at the capping layer may increase, and thus, may reduce a viewing angle.

The above information disclosed in this Background section is to enhance the understanding of the background of the present invention, and therefore, it may contain information that does not constitute prior art.

### SUMMARY

One or more aspects of example embodiments of the present invention provide an organic light emitting diode display in which a viewing angle is improved.

According to an embodiment of the present invention, an organic light emitting diode display includes: a first substrate; a switching thin film transistor on the first substrate; a driving thin film transistor on the first substrate; an organic light emitting diode connected to the driving thin film transistor; and a capping layer on the organic light emitting diode, the capping layer including an anisotropic material having a refractive index in a horizontal direction that is greater than a refractive index in a vertical direction.

The anisotropic material may include a perovskite structure.

The anisotropic material may include at least one of RbYbI₃, CsYbI₃, RbYbF₃, and CsYbF₃.

The capping layer may include a single layer.

The organic light emitting diode may include: a pixel electrode connected to the driving thin film transistor; a common electrode facing the pixel electrode; and an organic emission layer between the pixel electrode and the common electrode, and the capping layer may be on the common electrode.

The organic light emitting diode display may further include: a planarization layer between the pixel electrode and the driving thin film transistor; and a pixel defining layer at an edge portion of the pixel electrode on the planarization layer, and defining an opening to expose the pixel electrode.

The organic emission layer may be on the pixel electrode at the opening.

The common electrode may be on the pixel defining layer and on the organic emission layer.

The organic light emitting diode display may further include a second substrate attached to and sealed to the first substrate, and covering the organic light emitting diode.

The second substrate and the organic light emitting diode may be spaced from each other.

The organic light emitting diode display may further include a filler between the second substrate and the organic light emitting diode.

According to one or more aspects of example embodiments of the present invention, it may be possible to improve a viewing angle of an OLED display by applying a capping layer formed of an anisotropic material having a refractive index in a horizontal direction thereof that is greater than that in a vertical direction thereof.

### BRIEF DESCRIPTION OF THE DRAWINGS

The above and other aspects and features of the present invention will become apparent to those skilled in the art from the following detailed description of the example embodiments with reference to the accompanying drawings, in which like reference numerals refer to like elements throughout.

FIG. 1 illustrates an equivalent circuit diagram of a pixel of an organic light emitting diode display according to an exemplary embodiment of the present invention.

FIG. 2 illustrates a layout view of a pixel of an organic light emitting diode display according to an exemplary embodiment of the present invention.

FIG. 3 illustrates a cross-sectional view taken along the line III-III of the organic light emitting diode display of FIG. 2.

FIGS. 4-6 illustrate graphs of simulated reflection phases of internal light depending on a variation of a horizontal directional refractive index corresponding to a capping layer.

### DETAILED DESCRIPTION

Hereinafter, example embodiments will be described in more detail with reference to the accompanying drawings, in which like reference numbers refer to like elements throughout. The present invention, however, may be embodied in various different forms, and should not be construed as being limited to only the illustrated embodiments herein. Rather, these embodiments are provided as examples so that this disclosure will be thorough and complete, and will fully convey the aspects and features of the present invention to those skilled in the art. Accordingly, processes, elements, and techniques that are not necessary to those having ordinary skill in the art for a complete understanding of the aspects and features of the present invention may not be described. Unless otherwise noted, like reference numerals denote like elements throughout the attached drawings and the written description, and thus, descriptions thereof may not be repeated.

In the drawings, the relative sizes of elements, layers, and regions may be exaggerated for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present invention.

It will be understood that when an element or layer is referred to as being “on,” “connected to,” or “coupled to” another element or layer, it can be directly on, connected to, or coupled to the other element or layer, or one or more intervening elements or layers may be present. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present invention. As used herein, the singular forms “a” and “an” are intended to include the plural forms as well, unless the context clearly indicates otherwise. It will be further understood that the terms “comprises,” “comprising,” “includes,” and “including,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Expressions such as “at least one of,” when preceding a list of elements, modify the entire list of elements and do not modify the individual elements of the list.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present invention refers to “one or more embodiments of the present invention.” As used herein, the terms “use,” “using,” and “used” may be considered synonymous with the terms “utilize,” “utilizing,” and “utilized,” respectively. Also, the term “exemplary” is intended to refer to an example or illustration.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

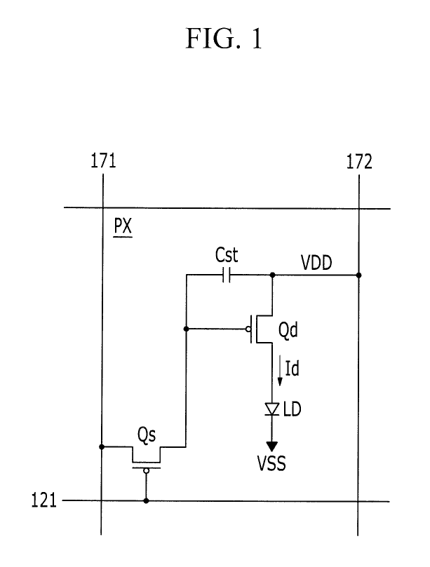

An organic light emitting diode display according to an exemplary embodiment of the present invention will now be described with reference to FIGS. 1 to 3.

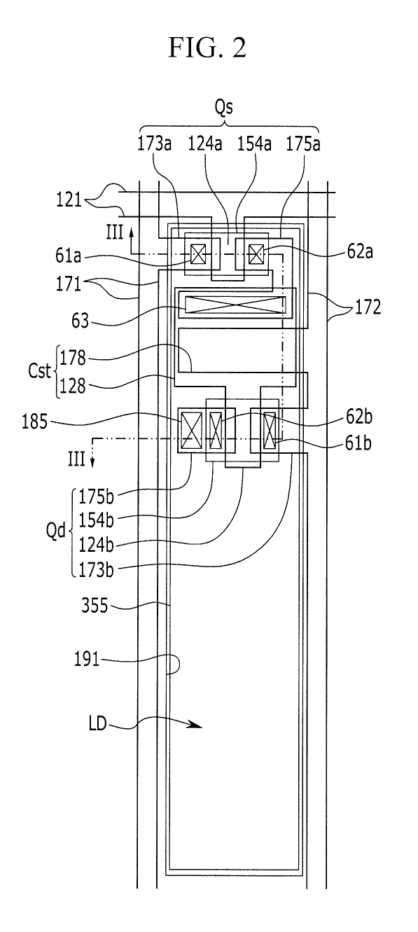

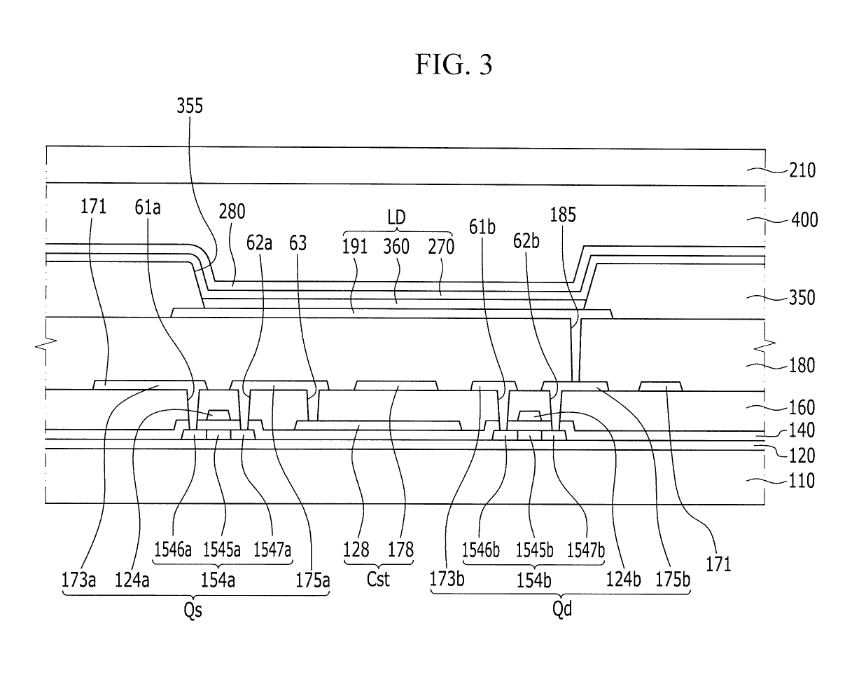

FIG. 1 illustrates an equivalent circuit diagram of a pixel of an organic light emitting diode display according to an exemplary embodiment of the present invention, FIG. 2 illustrates a layout view of a pixel of an organic light emitting diode display according to an exemplary embodiment of the present invention, and FIG. 3 illustrates a cross-sectional view taken along the line III-III of the organic light emitting diode display of FIG. 2.

Referring to FIG. 1, an organic light emitting diode display according to one or more exemplary embodiments of the present invention includes a plurality of signal lines 121, 171, and 172, and includes pixels PX connected to the plurality of signal lines 121, 171, and 172 and substantially arranged in a matrix form.

The signal lines 121, 171, and 172 include gate lines 121 for transmitting gate signals (or scan signals), data lines 171 for transmitting data signals, and driving voltage lines 172 for transmitting a driving voltage VDD.

The gate lines 121 extend substantially in a row direction and are substantially parallel to each other, and the data lines 171 and the driving voltage lines 172 extend substantially in a column direction and are substantially parallel to each other.

Each of the pixels PX includes a switching thin film transistor Qs, a driving thin film transistor Qd, a storage capacitor Cst, and an organic light emitting diode LD (or OLED).

The switching thin film transistor Qs includes a control terminal, an input terminal, and an output terminal. The control terminal is connected to the gate line 121, the input terminal is connected to the data line 171, and the output terminal is connected to the driving thin film transistor Qd. The switching thin film transistor Qs transmits the data signal applied to the data line 171 to the driving thin film transistor Qd in response to the gate signal applied to the gate line 121.

The driving thin film transistor Qd includes a control terminal, an input terminal, and an output terminal. The control terminal is connected to the switching thin film transistor Qs, the input terminal is connected to the driving voltage line 172, and the output terminal is connected to the organic light emitting diode LD. The driving thin film transistor Qd applies an output current Id to the organic light emitting diode LD, and the magnitude of the output current Id may vary according to the voltage applied between the control terminal and the input terminal of the driving thin film transistor Qd.

The storage capacitor Cst is connected between the control terminal and the input terminal of the driving thin film transistor Qd. The storage capacitor Cst charges the data signal that is applied to the control terminal of the driving thin film transistor Qd, and maintains or substantially maintains the charged data signal even after the switching thin film transistor Qs is turned off.

The organic light emitting diode LD includes an anode connected to the output terminal of the driving thin film transistor Qd, and a cathode connected to a common voltage VSS. The organic light emitting diode LD emits light, the intensity of which is varied according to the output current Id of the driving thin film transistor Qd, to display an image.

The switching thin film transistor Qs and the driving thin film transistor Qd may include n-channel field effect transistors (FET). However, the present invention is not limited thereto, and at least one of the switching thin film transistor Qs and the driving thin film transistor Qd may include a p-channel FET. Further, the connection relationship among the transistors Qs and Qd, the storage capacitor Cst, and the organic light emitting element LD may be modified in other embodiments.

Referring to FIG. 2 and FIG. 3, in an organic light emitting diode display, according to one or more exemplary embodiments of the present invention, a plurality of thin film structures are located on a substrate 110. Hereinafter, the plurality of thin film structures will be described in more detail.

A buffer layer 120 is on the substrate 110. The substrate 110 may include a transparent insulating substrate that is made of glass, quartz, ceramic, plastic, and/or the like. In another embodiment, the substrate 110 may include a metallic substrate made of stainless steel, and/or the like.

The buffer layer 120 may be formed as a single layer of a silicon nitride (SiNx), or may be formed as a multi-layer (e.g., a dual-layer) in which a silicon nitride (SiNx) and a silicon oxide (SiOx) are stacked. The buffer layer 120 may flatten a surface while preventing or reducing permeation of unwanted materials, such as impurities and/or moisture. The buffer layer 120 may be omitted, depending on the kind of substrate 110 and/or processing conditions.

A switching semiconductor layer 154a and a driving semiconductor layer 154b are spaced apart from each other on the buffer layer 120. The switching semiconductor layer 154a is made of polycrystalline silicon, and includes a switching channel region 1545a, a switching source region 1546a, and a switching drain region 1547a. The driving semiconductor layer 154b is made of polycrystalline silicon, and includes a driving channel region 1545b, a driving source region 1546b, and a driving drain region 1547b. Here, the switching source region 1546a and the switching drain region 1547a may be at opposite sides of the switching channel region 1545a, and the driving source region 1546b and the driving drain region 1547b may be at opposite sides of the driving channel region 1545b.

The switching and driving channel regions 1545a and 1545b may be a polycrystalline silicone, which is not doped with an impurity (e.g., an intrinsic semiconductor), and the switching and driving source regions 1546a and 1546b and the switching and driving drain regions 1547a and the 1547b may be a polycrystalline silicon that is doped with a conductive impurity (e.g., an impurity semiconductor).

A gate insulating layer 140 is on the buffer layer 120, on the switching semiconductor layer 154a, and on the driving semiconductor layer 154b. The gate insulating layer 140 may be a single layer, or may be multiple layers including at least one of a silicon nitride and a silicon oxide

The gate line 121 and a first storage capacitor plate 128 are on the gate insulating layer 140.

The gate line 121 extends in a horizontal direction (e.g., a row direction) to transmit the gate signal, and includes a switching gate electrode 124a that protrudes from the gate line 121 to the switching semiconductor layer 154a. Here, the switching gate electrode 124a overlaps the switching channel region 1545a.

The first storage capacitor plate 128 includes, or is connected to, a driving gate electrode 124b that protrudes from the first storage capacitor plate 128 to the driving semiconductor layer 154b. Here, the driving gate electrode 124b overlaps the driving channel region 1545b.

An interlayer insulating layer 160 is on the gate line 121, on the first storage capacitor plate 128, and on the buffer layer 120. The interlayer insulating layer 160 may be a single layer, or may be multiple layers including at least one of a silicon nitride and a silicon oxide.

The interlayer insulating layer 160 and the gate insulating layer 140 define a switching source exposure hole 61a and a switching drain exposure hole 62a, through which the switching source region 1546a and the switching drain region 1547a are exposed, respectively. The interlayer insulating layer 160 and the gate insulating layer 140 also define a driving source exposure hole 61b and a driving drain exposure hole 62b, through which the driving source region 1546b and the driving drain region 1547b are exposed, respectively. Further, the interlayer insulating layer 160 defines a first contact hole 63 through which a portion of the first storage capacitor plate 128 is exposed.

The data line 171, the driving voltage line 172, the switching drain electrode 175a, and the driving drain electrode 175b are on the interlayer insulating layer 160.

The data line 171 includes a switching source electrode 173a, which transmits the data signal, extends in a crossing direction with the gate line 121, and protrudes toward the switching semiconductor layer 154a from the data line 171.

The driving voltage line 172 transmits the driving voltage, is separated (e.g., spaced) from the data line 171, and extends in the same or substantially the same direction as that of the data line 171. The driving voltage line 172 includes the driving source electrode 173b, which protrudes toward the driving semiconductor layer 154b from the driving voltage line 172, and also includes a second storage capacitor plate 178, which protrudes from the driving voltage line 172 to overlap the first storage capacitor plate 128. Here, the first storage capacitor plate 128 and the second storage capacitor plate 178 form the storage capacitor Cst by using the interlayer insulating layer 160 as a dielectric material.

The switching drain electrode 175a faces the switching source electrode 173a, and the driving drain electrode 175b faces the driving source electrode 173b.

The switching source electrode 173a and the switching drain electrode 175a are connected to the switching source region 1546a and the switching drain region 1547a through the switching source exposure hole 61a and the switching drain exposure hole 62a, respectively. Further, the switching drain electrode 175a is electrically connected to the first storage capacitor plate 128 and the driving gate electrode 124b through the first contact hole 63 formed in the interlayer insulating layer 160.

The driving source electrode 173b and the driving drain electrode 175b are connected to the driving source region 1546b and the driving drain region 1547b through the driving source exposure hole 61b and the driving drain exposure hole 62b, respectively.

The switching semiconductor layer 154a, the switching gate electrode 124a, the switching source electrode 173a, and the switching drain electrode 175a form the switching thin film transistor Qs, and the driving semiconductor layer 154b, the driving gate electrode 124b, the driving source electrode 173b, and the driving drain electrode 175b form the driving thin film transistor Qd.

A planarization layer 180 is on the interlayer insulating layer 160, on the data line 171, on the driving voltage line 172, on the switching drain electrode 175a, and on the driving drain electrode 175b. The planarization layer 180 may be made of an organic material, and an upper surface of the planarization layer 180 may be flattened/planar. The planarization layer 180 defines a second contact hole 185 through which the driving drain electrode 175b is exposed.

The organic light emitting diode LD and a pixel defining layer 350 are on the planarization layer 180.

The organic light emitting diode LD includes a pixel electrode 191, an organic emission layer 360, and a common electrode 270.

The pixel electrode 191 is on the planarization layer 180, and is electrically connected to the driving drain electrode 175b of the driving thin film transistor Qd through the second contact hole 185 formed on the planarization layer 180. The pixel electrode 191 is an anode of the organic light emitting diode LD.

The pixel electrode 191 may be made of a reflective metal, such as lithium (Li), calcium (Ca), lithium fluoride/calcium (LiF/Ca), lithium fluoride/aluminum (LiF/Al), aluminum (Al), silver (Ag), magnesium (Mg), and/or gold (Au).

The pixel defining layer 350 is located at an edge portion of the pixel electrode 191 on the planarization layer 180, and includes an opening 355 through which the pixel electrode 191 is exposed. For example, the edge portion of the pixel electrode 191 may be below the pixel defining layer 350.

The organic emission layer 360 is on the pixel electrode 191 in the opening 355 of the pixel defining layer 350.

The organic emission layer 360 may include multiple layers including at least one of an emission layer, a hole-injection layer (HIL), a hole-transporting layer (HTL), an electron-transporting layer (ETL), and an electron-injection layer (EIL). When the organic emission layer 360 includes each of these layers, the hole-injection layer may be on the pixel electrode 191 as the anode, and the hole-transporting layer, the emission layer, the electron-transporting layer, and the electron-injection layer may be sequentially stacked thereon.

The organic emission layer 360 may include a red organic emission layer for emitting red light, a green organic emission layer for emitting green light, and/or a blue organic emission layer for emitting blue light. The red organic emission layer, the green organic emission layer, and the blue organic emission layer are respectively formed on a red pixel, a green pixel, and a blue pixel to collectively implement a color image.

In some embodiments, the red organic emission layer, the green organic emission layer, and the blue organic emission layer may be integrally stacked on the organic emission layer 360, together with the red pixel, the green pixel, and the blue pixel, to respectively form a red color filter, a green color filter, and a blue color filter in each pixel so as to implement a color image. Alternatively, a white organic emission layer for emitting white light may be formed on each of the red pixel, the green pixel, and the blue pixel, and a red color filter, a green color filter, and a blue color filter may be respectively formed for the pixels to implement a color image. When the color image is implemented by using the white organic emission layer and the color filters, a deposition mask for depositing the red organic emission layer, the green organic emission layer, and the blue organic emission layer on individual pixels, that is, the red pixel, the green pixel, and the blue pixel, may be omitted.

The white organic emission layer according to some other exemplary embodiments of the present invention may be formed to have a single organic emission layer, or may include a plurality of organic emission layers that are stacked to emit white light. For example, there may be included a configuration in which at least one yellow organic emission layer and at least one blue organic emission layer may be combined to emit white light, a configuration in which at least one cyan organic emission layer and at least one red organic emission layer may be combined to emit white light, and/or a configuration in which at least one magenta organic emission layer and at least one green organic emission layer may be combined to emit white light.

The common electrode 270 is on the pixel defining layer 350 and on the organic emission layer 360. The common electrode 270 may be made of a transparent conductive material, such as indium tin oxide (ITO), indium zinc oxide (IZO), zinc oxide (ZnO), and/or indium oxide (In₂O₃). The common electrode 270 may be a cathode of the organic light emitting diode LD.

A capping layer 280 is on the common electrode 270. The capping layer 280 may assist with effectively transmitting the light generated in organic emission layer 360 to the outside, and may protect the organic light emitting diode LD.

The capping layer 280 is formed of an anisotropic material of which a refractive index in a horizontal direction thereof is different from a refractive index in a vertical direction thereof. In another embodiment, the capping layer 280 is formed of an anisotropic material with a perovskite structure of which the refractive index in the horizontal direction is greater than that in the vertical direction.

The perovskite structure is a crystal structure having a chemical formula of ABX₃, in which A and B are metals, and in which X is an oxygen or a halogen. According to an exemplary embodiment, the capping layer 280 may include at least one of RbYbI₃, CsYbI₃, RbYbF₃, and CsYbF₃.

Generally, the greater the refractive index of a layer, the slower the speed of light passing through the layer. When light passes through the capping layer 280, the light proceeds in the vertical and horizontal directions.

When the refractive index in the horizontal direction is the same or substantially the same as the refractive index in the vertical direction, the speed of light passing through in the horizontal direction is the same or substantially the same as the speed of light passing through in the vertical direction. Assuming that a thickness of the capping layer 280 through which light passes is d, assuming the refractive index of the capping layer 280 is n, and assuming an angle of light incident to the capping layer 280 is θ, then the path of light passing through the capping layer 280 may be determined by 2ndcos θ. In this case, when the path of light is an integer multiplied by the wavelength of the light, constructive interference is generated, and when a viewing angle increases, the θ increases, so that the path of light decreases. Accordingly, when viewed from a viewing angle direction (e.g., in the horizontal direction), because the wavelength of the light in which the constructive interference is generated is shortened, a phase is blue-shifted in the horizontal direction. Accordingly, the viewing angle characteristic deteriorates.

According to one or more embodiments of the present invention, by using the capping layer 280 of which the refractive index in the horizontal direction thereof is greater than that in the vertical direction thereof, because the speed of light passing through in the horizontal direction is slower than the speed of light passing through in the vertical direction, it may be possible to reduce an amount of the phase from being blue-shifted in the horizontal direction (e.g., the viewing angle direction). Thus, the viewing angle characteristic of the organic light emitting diode display may be improved.

The capping layer 280 may be a single layer formed of an anisotropic material having the perovskite structure of which the refractive index in the horizontal direction is greater than that in the vertical direction.

When the capping layer of multiple layers having different refractive indexes is used to improve light extracting efficiency, the reflection of the internal light therein may increase, so the viewing angle is reduced. According to one or more example embodiments of the present invention, by including the capping layer 280 of the single layer formed of the anisotropic material having the perovskite structure of which the refractive index in the horizontal direction is greater than that in the vertical direction, it may be possible to improve the viewing angle of the organic light emitting diode display as described above.

A second substrate 210 is on the capping layer 280. The second substrate 210 is attached to the first substrate 110 by a sealant to function as an encapsulation substrate. In this case, the second substrate 210 and the organic light emitting diode LD are spaced from each other, and a filler 400 may be arranged in a space that is defined by the second substrate 210 and the organic light emitting diode LD being spaced from each other. Since the filler 400 fills the space inside the organic light emitting diode display, the strength and/or durability of the organic light emitting diode display may be improved.

A spacer for maintaining an interval between the first substrate 110 and the second substrate 210 may be arranged therebetween.

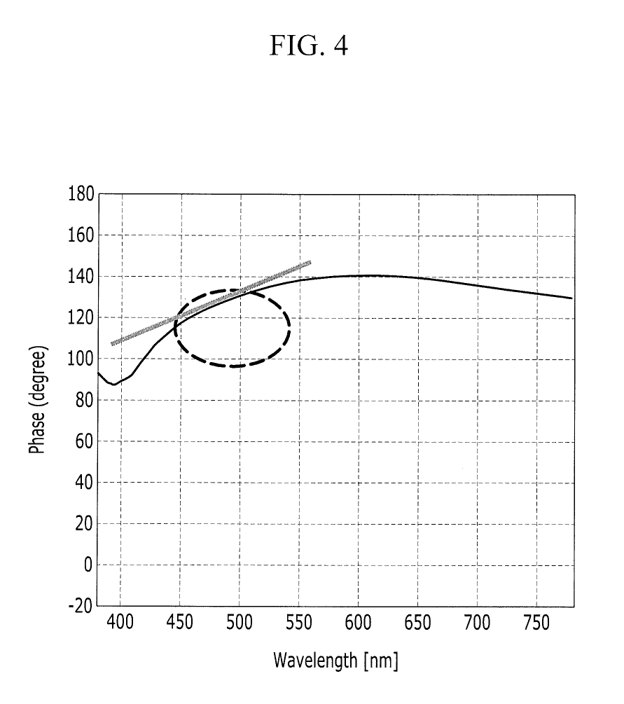

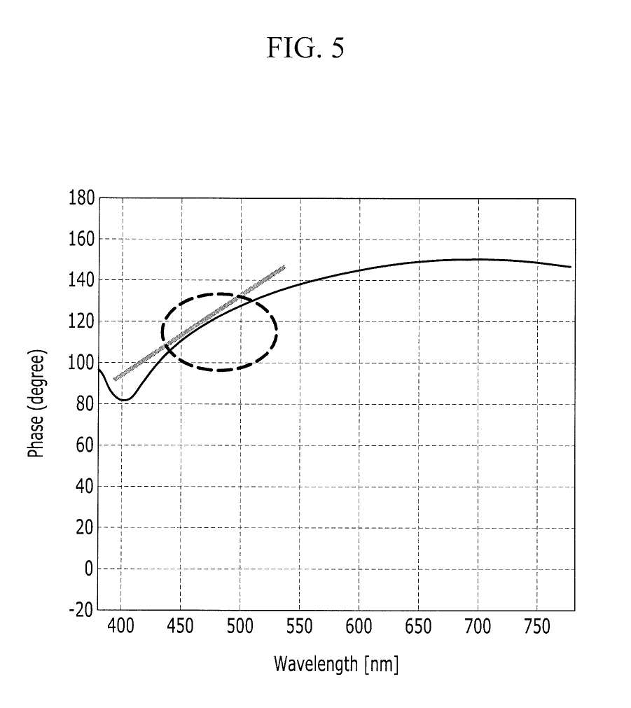

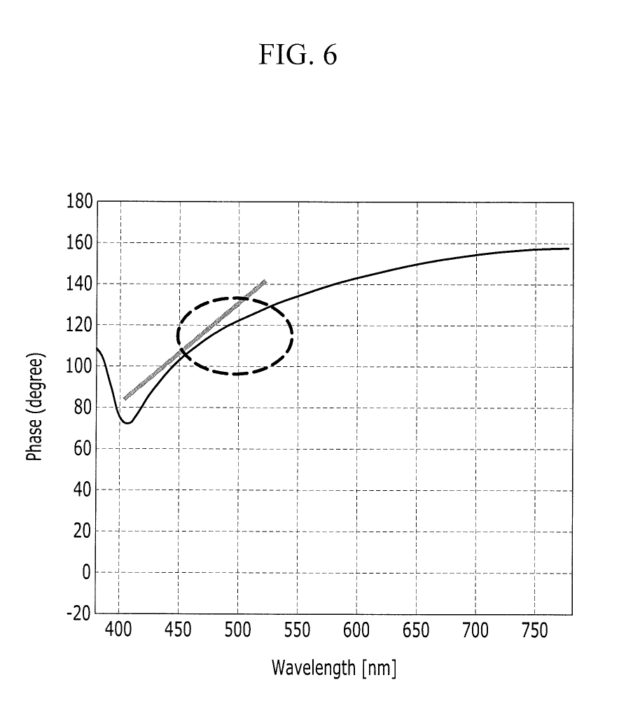

Characteristics of the viewing angle of the organic light emitting diode display corresponding to the capping layer will be described in more detail with reference to FIG. 4, FIG. 5, and FIG. 6.

FIG. 4 is a graph showing simulated characteristics of the reflection phase of internal light when the horizontal refractive index and the vertical refractive index of the capping layer are the same or substantially the same.

FIG. 5 is a graph showing simulated characteristics of the reflection phase of internal light in the capping layer having a horizontal refractive index that is increased by about 0.2 from that of FIG. 4.

FIG. 6 is a graph showing simulated characteristics of the reflection phase of internal light in the capping layer having a horizontal refractive index that is increased by about 0.4 from that of FIG. 4.

Referring to FIG. 4, FIG. 5, and FIG. 6, it is shown that phase slopes in a blue wavelength are about 0.311, 0.39, and 0.435, respectively. That is, as the horizontal refractive index of the capping layer is increased to be larger than that of the vertical refractive index, the phase slopes in the blue wavelength increase. As the reflection phase slope of the internal light in the capping layer increases, the variation of the phase increases, and a red-shift may occur. In FIG. 4, FIG. 5, and FIG. 6, when moving to a left side of the graph or a right side of the graph from a point at which a wavelength is about 460 nm, the variation of the phase occurs in proportion to the phase slope.

That is, as the horizontal refractive index of the capping layer becomes larger than that of the vertical refractive index, the red shift occurs, and thus, the viewing angle characteristic is improved by compensating for the blue shift at the left and right directions (e.g., the viewing angle directions).

Although example embodiments of the present invention have been described, it will be understood that the present invention is not limited to these example embodiments, and that various changes and modifications may be made as understood by those of ordinary skilled in the art within the spirit and scope of the present invention as defined in the following claims, and their equivalents.

What is claimed is:

1. An organic light emitting diode display comprising:
a first substrate;
a switching thin film transistor on the first substrate;
a driving thin film transistor on the first substrate;
an organic light emitting diode connected to the driving thin film transistor; and
a capping layer on the organic light emitting diode, the capping layer comprising an anisotropic material having a refractive index in a horizontal direction that is greater than a refractive index in a vertical direction.

2. The organic light emitting diode display of claim 1, wherein the anisotropic material comprises a perovskite structure.

3. The organic light emitting diode display of claim 2, wherein the anisotropic material comprises at least one of RbYbI₃, CsYbI₃, RbYbF₃, and CsYbF₃.

4. The organic light emitting diode display of claim 3, wherein the capping layer comprises a single layer.

5. The organic light emitting diode display of claim 1, wherein the organic light emitting diode comprises:
a pixel electrode connected to the driving thin film transistor;
a common electrode facing the pixel electrode; and
an organic emission layer between the pixel electrode and the common electrode, and
wherein the capping layer is on the common electrode.

6. The organic light emitting diode display of claim 5, further comprising:
a planarization layer between the pixel electrode and the driving thin film transistor; and
a pixel defining layer at an edge portion of the pixel electrode on the planarization layer, and defining an opening to expose the pixel electrode.

7. The organic light emitting diode display of claim 6, wherein the organic emission layer is on the pixel electrode at the opening.

8. The organic light emitting diode display of claim 7, wherein the common electrode is on the pixel defining layer and on the organic emission layer.

9. The organic light emitting diode display of claim 1, further comprising a second substrate attached to and sealed to the first substrate, and covering the organic light emitting diode.

10. The organic light emitting diode display of claim 9, wherein the second substrate and the organic light emitting diode are spaced from each other.

11. The organic light emitting diode display of claim 10, further comprising a filler between the second substrate and the organic light emitting diode.
